(19) United States
(12) Patent Application Publication
(10) Pub. No.: US 2026/0235965 A1
(43) Pub. Date: Aug. 13, 2026

(54) METHOD AND SYSTEM FOR SELECTING PATTERNS BASED ON SIMILARITY METRIC

(71) Applicant: ASML NETHERLANDS B.V., Veldhoven (NL)

(72) Inventors: Xiaogai TANG, Fremont, CA (US); Wei-Chou LIN, Fremont, CA (US)

(73) Assignee: ASML NETHERLANDS B.V., Veldhoven (NL)

(21) Appl. No.: 19/151,445

(22) PCT Filed: Jan. 25, 2024
(86) PCT No.: PCT/EP2024/051824

§ 371 Date: Jul. 28, 2025

Related U.S. Application Data
(60) Provisional application No. 63/447,598, filed on Feb. 22, 2023.

(51) Int. Cl. G03F 7/00

(52) U.S. Cl. CPC G03F 7/706837; G03F 7/706839

(57) ABSTRACT

Methods and systems for selecting patterns from one set to another set. A first set of patterns and a second set of patterns represented in a pattern representation space are obtained. For each pattern in the second set of patterns, a similarity metric that is indicative of a similarity between the corresponding pattern and patterns in the first set of patterns in the pattern representation space is determined. A specified pattern is selected from the second set of patterns for updating the first set of patterns based on the similarity metric.

### CROSS-REFERENCE TO RELATED APPLICATION

This application claims priority of U.S. application 63/447,598 which was filed on 22 Feb. 2023 and which is incorporated herein in its entirety by reference.

### TECHNICAL FIELD

The embodiments provided herein relate to semiconductor manufacturing, and more particularly to semiconductor metrology and inspection.

### BACKGROUND

A lithographic apparatus is a machine that applies a desired pattern onto a target portion of a substrate. This process of transferring the desired pattern to the substrate is called a patterning process. The patterning process can include a patterning step to transfer a pattern from a patterning device (such as a mask) to the substrate. Various variations (e.g., variations in the patterning process or the lithographic apparatus) can potentially limit lithography implementation for semiconductor high volume manufacturing (HVM). High resolution images of a substrate, such as images obtained using a scanning electron microscope (SEM), may be inspected for determining any defects in the patterning process. Pattern selection is a process of selecting patterns (e.g., diverse or different patterns) from a number of patterns. One of the applications for pattern selection includes using the diverse set of patterns as training data to calibrate or train models (e.g., physical model, artificial intelligence (AI) model, empirical model, rule-based model, etc.) to predict corresponding results that further facilitates a patterning process. Selecting an appropriate set of patterns is one of the important factors in improving a pattern coverage of a model. Another application for pattern selection is metrology and defect inspection.

Metrology processes are used at various steps during a patterning process to monitor and/or control the process. For example, metrology processes are used to measure one or more characteristics of a substrate, such as a relative location (e.g., registration, overlay, alignment, etc.) or dimension (e.g., line width, critical dimension (CD), thickness, etc.) of features formed on the substrate during the patterning process or stochastic variation, such that, for example, the performance of the patterning process can be determined from the one or more characteristics. If the one or more characteristics are unacceptable (e.g., out of a predetermined range for the characteristic(s)), one or more variables of the patterning process may be designed or altered, e.g., based on the measurements of the one or more characteristics, such that substrates manufactured by the patterning process have an acceptable characteristic(s).

### BRIEF SUMMARY

In some aspects, the techniques described herein relate to a method for selecting patterns. The method includes: obtaining a first set of patterns and a second set of patterns represented in a pattern representation space; obtaining, for each pattern in the second set of patterns, a similarity metric that is indicative of a similarity between the corresponding pattern and patterns in the first set of patterns, wherein the similarity is determined in the pattern representation space; and selecting a specified pattern from the second set of patterns for updating the first set of patterns based on the similarity metric.

In some aspects, the techniques described herein relate to a method for selecting patterns. The method includes: obtaining a first set of patterns and a second set of patterns represented in a feature vector space; obtaining, for each pattern in the second set of patterns, distance information indicating distances in the feature vector space between the corresponding pattern and patterns in the first set of patterns; and selecting a specified pattern form the second set of patterns for updating the first set of patterns based on the distance information.

In some aspects, the techniques described herein relate to an apparatus including: a memory storing a set of instructions; and a processor configured to execute the set of instructions to cause the apparatus to perform a method of any of the above embodiments.

In some aspects, the techniques described herein relate to a non-transitory computer-readable medium having instructions recorded thereon, the instructions when executed by a computer implementing the method of any of the above embodiments.

### BRIEF DESCRIPTION OF THE DRAWINGS

Embodiments will now be described, by way of example only, with reference to the accompanying drawings in which:

FIG. 1 is a block diagram of an exemplary system for selecting patterns from one set for adding to another set, consistent with various embodiments.

FIG. 2 is a block diagram of a system for determination of pattern coverage of a first set of patterns with respect to a second set of patterns, consistent with various embodiments.

FIG. 3 is a flow diagram of an exemplary method for selecting patterns from one set for adding to another set, consistent with various embodiments.

FIG. 4 is a block diagram of an example computer system, according to an embodiment.

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

### DETAILED DESCRIPTION

Conventional techniques employ various methods for pattern selection. For example, one method employs image-based pattern selection in which images of patterns are encoded to feature vectors, which are then processed using a clustering method (e.g., k-means) to generate clusters of similar patterns. A set of diverse patterns may then be created by selecting patterns from the various clusters. However, in the clustering method a user may have minimum to no control on what patterns to select and has to do with the patterns the method selects for the user. In another example, if a set of diverse patterns is already selected by the user and the user wants to increase pattern coverage and add additional patterns from a candidate set that are unique compared to the patterns in the selected set, the conventional methods do not facilitate such a selection method. Next, the conventional techniques may not provide a way to quantify the pattern coverage (e.g., how diverse is the selected set of patterns). So, the user may not know if the pattern coverage of the selected set is good enough for their intended application or whether additional patterns have to be selected. Further, even if the user wants to add additional patterns to the selected set of patterns, the methods do not allow addition of more patterns to the already selected set of patterns and instead may require the user to start over the pattern selection method from the beginning, which consumes significant time and computing resources. These and other drawbacks exist.

Disclosed are embodiments for selecting patterns from one set of patterns for adding to another set of patterns based on a similarity metric between the patterns of two sets. A pattern may be selected from a candidate set of patterns to be added to a selected set of patterns (e.g., a set of patterns that are diverse) based on one or more similarity metrics between a pattern in the candidate set of patterns and each pattern of the selected set of patterns. For example, the patterns may be represented in a feature vector space, and a pattern may be added from the candidate set of patterns to the selected set of patterns based on a feature vector distance between the feature vectors of the patterns in the candidate set of patterns and each pattern of the selected set of patterns. The pattern coverage of the selected set of patterns may also be determined or quantified based on the number of patterns for a given feature vector distance of a set of feature vector distances, and typically the more the number of patterns having lesser feature vector distances with the patterns in the candidate set of patterns, the better the pattern coverage of the selected set. The embodiments may continue to add patterns to the selected set of patterns from the candidate set of patterns iteratively until a desired pattern coverage is obtained. The above embodiments provide various advantages over conventional techniques of pattern selection. For example, the above embodiments not only provide the freedom for a user to select a set of patterns deemed diverse, but also enable the user to iteratively add additional patterns to the selected set of patterns to enhance pattern coverage, which is in contrast with the conventional techniques where the selection process has to be started from the beginning to select additional patterns. Further, by allowing the user to determine the pattern coverage, the embodiments allows to evaluate pattern coverage and decide whether to add additional patterns from the candidate set of patterns. Thus, the embodiments provide an improved pattern selection process.

The following paragraphs describe a system and a method for selecting patterns from one set of patterns for updating another set of patterns based on a similarity metric between the patterns of two sets. A first set of patterns may include patterns that are different from each other. The first set of patterns (also referred to as “selected set of patterns”) may be generated in a number of ways, for example, via user selection or automatic selection as described below. A second set of patterns (also referred to as “candidate set of patterns”) is a set from which one or more patterns are selected for adding to the selected set of patterns. For example, those patterns of the candidate set of patterns that are considered to be different with respect to each of the patterns in the selected set of patterns are selected for adding to the selected set of patterns. A pattern may be selected from the candidate set of patterns based on a similarity between the patterns in the candidate set of patterns and each pattern of the selected set of patterns. In some embodiments, a candidate pattern may be selected if the candidate pattern is the least similar pattern among all the patterns in the candidate set to each of the patterns in the selected set of patterns.

The patterns may be represented in any pattern representation space and a similarity metric is determined based on the pattern representation space. For example, the patterns may be represented in a feature vector space in which each of the patterns from both the sets are represented as corresponding feature vectors, and a similarity metric may include a feature vector distance between feature vectors of the patterns in the candidate set of patterns and each pattern of the selected set of patterns. In some embodiments, a candidate pattern that has the largest first nearest neighbor distance feature vector among all the patterns in the candidate set to the patterns in the selected set of patterns may be selected for addition to the selected set of patterns. In another example, the patterns may be represented in an image representation space in which each of the patterns from both the sets are represented as images (e.g., an aerial image, a resist image, an etch image, a scanned electron microscopy (SEM) image or other metrology tool generated image, a simulated image, etc.) and a similarity metric may include any metric that is indicative of a similarity between the images of patterns in the candidate set of patterns and an image of each pattern of the selected set of patterns. The following paragraphs describe the pattern selection using feature vector space and feature vector distance as examples of the pattern representation space and similarity metric, respectively. However, it should be noted that neither the pattern representation space is limited to the feature vector space, nor the similarity metric is limited to the feature vector distance, and the embodiments are applicable to other representation spaces or similarity metrics.

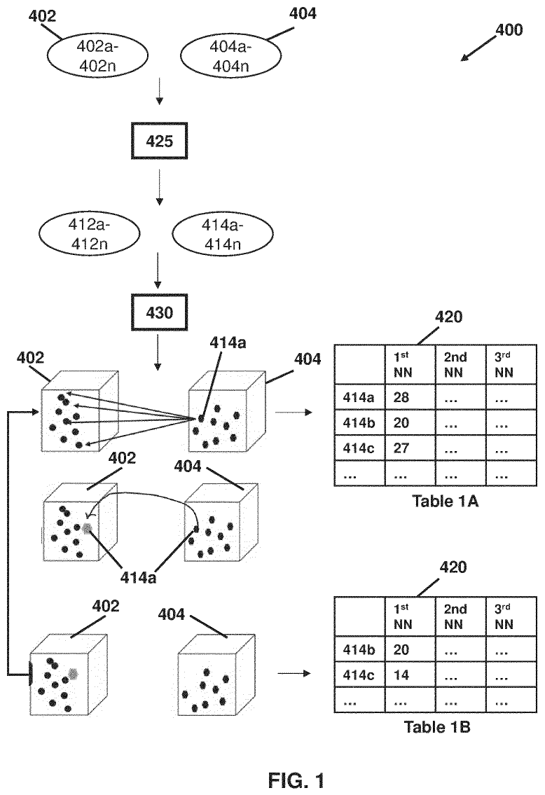

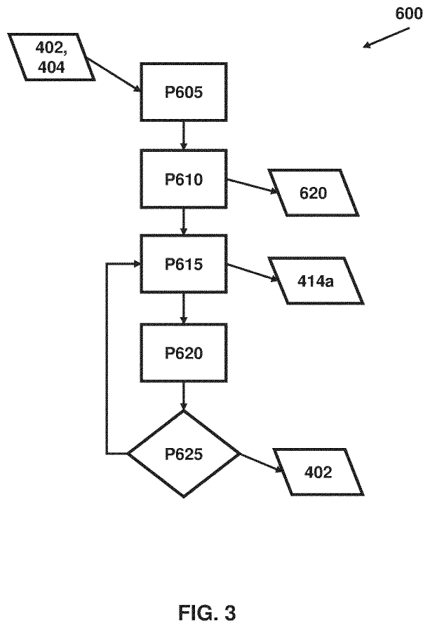

FIG. 1 is a block diagram of an exemplary system 400 for selecting patterns from one set for adding to another set to increase pattern coverage, consistent with various embodiments. FIG. 3 is a flow diagram of an exemplary method 600 for selecting patterns from one set for adding to another set, consistent with various embodiments.

At process P605, a pattern representation component 425 obtains two sets of patterns. For example, a first set of patterns may be a selected set of patterns 402 that may include patterns 402a-402n that are considered diverse (e.g., by a user). A second set of patterns may be a candidate set of patterns 404 from which those patterns 404a-40n that are considered to be different or diverse with respect to the patterns in the selected set of patterns 402 may have to be selected for adding to the selected set of patterns 402. The patterns 402a-402n and 404a-404n may be obtained in a number of formats. For example, a pattern may be obtained as a target layout (e.g., graphic design system (GDS) file) of the pattern to be printed on a substrate. In another example, the pattern may be obtained as an image of the pattern (an aerial image, a resist image, an etch image, a SEM image or other metrology tool generated image, a simulated image, etc.).

At process P610, a pattern selection component 430 determines a similarity metric 620 for each pattern in the candidate set of patterns 404 that is indicative of a similarity between the corresponding pattern and each pattern of the selected set of patterns 402. In some embodiments, the similarity metric 620 may be determined based on a pattern representation space in which the patterns are represented. As described above, the pattern representation space may include an image representation space in which each of the patterns from both the sets are represented as images examples of which are mentioned above. The similarity metric 620 in the image representation space may be a metric that is indicative of a pattern similarity between the images of patterns in the candidate set of patterns 404 and images of patterns in the selected set of patterns 402. The similarity between two images may be determined in any of a number of ways that are well known in the art.

In some embodiments, the pattern representation space may include a feature vector space in which each of the patterns is represented as a feature vector. For example, the pattern representation component 425 generates feature vectors 412a-412n for the patterns 402a-402n, respectively, and feature vectors 414a-414n for the patterns 404a-404n, respectively. A feature vector may be generated in a number of ways. For example, a pattern may be encoded to a feature vector (e.g., using an autoencoder model). In some embodiments, the similarity metric 620 in the feature vector space is determined using a feature vector distance 420 that is indicative of a distance between two feature vectors. The distance between two feature vectors may be determined in a number of ways that are well known in the art. The pattern selection component 430 determines, for each pattern in the candidate set of patterns 404, a distance between the feature vector of the corresponding pattern and a feature vector of each pattern in the selected set of patterns 402. For example, for a first pattern 404a in the candidate set of patterns 404, the pattern selection component 430 determines the feature vector distance between the feature vector 414a of the first pattern 404a and a feature vector of each of the patterns in the selected set of patterns 402. The pattern selection component 430 then determines the nearest neighbor distances of the first pattern 404a with the patterns in the selected set of patterns 402 by ranking or sorting the feature vector distances. Table 1A of FIG. 1 shows the nearest neighbor distance between the patterns of the two sets. For example, the first row of Table 1A shows the nearest neighbor distance between the feature vector 414a of the first pattern 404a and the feature vector of each of the patterns in the selected set of patterns 402. Similarly, the second row of the Table 1A shows the nearest neighbor distance between the feature vector 414b of a second pattern 404b and the feature vector of each of the patterns in the selected set of patterns 402. Similarly, other rows show the distances between other patterns of the candidate set of patterns 404 and the selected set of patterns 402. In some embodiments, the nearest neighbor distances of the candidate set of patterns 404 are ranked based on the distances. For example, as illustrated in Table 1A, the nearest neighbor distances of the feature vector 414a are arranged in a descending order with a first column representing a largest nearest neighbor distance and a last column representing the smallest nearest neighbor distance.

At process P615, the pattern selection component 430 selects a specified pattern from the candidate set of patterns 404 to be added to the selected set of patterns 402 based on the similarity metric 620. In some embodiments, the pattern selection component 430 chooses a specified pattern 404a (e.g., corresponding to feature vector 414a) that has the largest first nearest neighbor distance among the patterns in the candidate set of patterns 404. In some embodiments, the pattern with the largest first nearest neighbor distance is the most diverse pattern among all the patterns of the candidate set of patterns 404 with respect to the selected set of patterns 402. For example, referring to Table 1A, the first nearest neighbor distances of the patterns 404a-404n (e.g., feature vectors 414a-414n) are “28,” “20,” “27,” and so on, and the feature vector 414a has the largest first nearest neighbor distance (e.g., “28”), and therefore, the pattern selection component 430 selects the specified pattern 404a corresponding to the feature vector 414a to be added to the selected set of patterns 402.

After selecting the specified pattern 404a, the pattern selection component 430 moves the selected pattern 404a from the candidate set of patterns 404 to the selected set of patterns 402.

At process P620, the pattern selection component 430 updates the similarity metric 620 for the remaining patterns of the candidate set of patterns 404. In some embodiments, when a pattern is moved from one set to another set, the feature vector distances 420 for some of the remaining patterns in the candidate set of patterns 404 may change. For example, when the specified pattern 404a (e.g., feature vector 414a) is moved from the candidate set of patterns 404 to the selected set of patterns 402, the nearest neighbor distance of at least some of the remaining patterns 404b-404n (e.g., feature vectors 414b-414n) may change. For example, as illustrated in Table 1B, the first nearest neighbor distance of the feature vector 414c has changed from “27” to “14,” while the first nearest neighbor distance of the feature vector 414b has remained the same. In some embodiments, this is in accordance with the pattern selection based on the similarity metric. That is, when a given pattern (e.g., feature vector 414a) having the largest first nearest neighbor distance is determined to be diverse with reference to the selected set of patterns 402, then another pattern having the next largest first nearest neighbor distance (e.g., feature vector 414c) is typically less diverse after the given pattern (e.g., feature vector 414a) is moved to the selected set of patterns 402, and accordingly, the first nearest neighbor distance of the other pattern (e.g., feature vector 414c) decreases from its initial value. While the nearest neighbor distances of some of the patterns may change after the specified pattern 404a is moved to the selected set of patterns 402, the nearest neighbor distances of the other patterns in the candidate set of patterns 404 may not change (e.g., the feature vector 414b). Since the selected set of patterns 402 contain a set of diverse patterns, in some embodiments, the nearest neighbor distances between each of the patterns in the selected set of patterns 402 would be above a specified threshold.

At determination process P625, the pattern selection component 430 determines whether a specified criterion for outputting the selected set of patterns 402 is satisfied. Based on a determination that the specified criterion is not satisfied, the pattern selection component 430 continues to select an additional pattern from the candidate set of patterns 404 to be added to the selected set of patterns 402 by proceeding to process P615. Further selection of the additional patterns may be triggered by user input or automatically. Based on a determination that the specified criterion is satisfied, the pattern selection component 430 outputs the selected set of patterns 402. That is, the method 600 continues to add patterns from the candidate set of patterns 404 to the selected set of patterns 402 iteratively until the specified criterion is satisfied.

The specified criterion for outputting the selected set of patterns 402 may include a number of parameters. In some embodiments, the specified criterion includes at least one of (a) a number of iterations, (b) a number or percentage of patterns selected from the candidate set of patterns, (c) a total number of patterns in the selected set of patterns, or (d) a first nearest neighbor distance. For example, the method 600 may continue to add patterns to the selected set of patterns 402 until a threshold number of iterations are executed, and output the selected set of patterns 402 when the threshold number of iterations is satisfied. In another example, the method 600 may continue to add patterns to the selected set of patterns 402 until a threshold number of patterns or a threshold percentage of patterns are selected from the candidate set of patterns 404, and output the selected set of patterns 402 when the threshold number of patterns or a threshold percentage of patterns are selected. In another example, the method 600 may continue to add patterns to the selected set of patterns 402 until the selected set of patterns 402 has a threshold number of patterns. In another example, the method 600 may continue to add patterns to the selected set of patterns 402 until the pattern coverage is satisfied. In some embodiments, the pattern coverage may be determined based on a number of patterns and their associated similarity metric values. For example, the more the number of patterns with larger first nearest neighbor distances in the candidate set of patterns 404, the lesser is the pattern coverage of the selected set of patterns 404. The figure below illustrates the determination of pattern coverage.

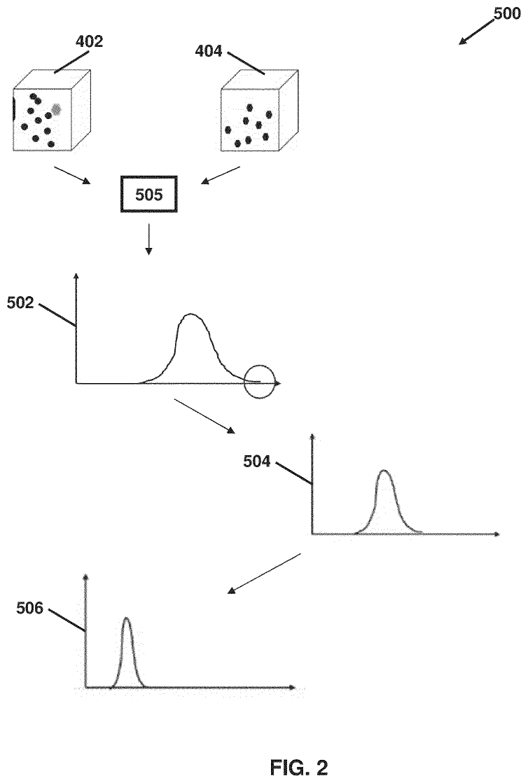

FIG. 2 is a block diagram of a system 500 for determination of pattern coverage of a first set of patterns with respect to a second set of patterns, consistent with various embodiments. In some embodiments, a pattern coverage component 505 may determine the pattern coverage based on a count or number of the patterns for the various similarity metric values. For example, the pattern coverage component 505 may determine the pattern coverage of the selected set of patterns 402 based on the first nearest neighbor distance associated with each of the patterns of the candidate set of patterns 404 (which is determined as described at least with reference to FIGS. 1 and 3) and a count or number of the patterns for the various first nearest neighbor distances. That is, if the first nearest neighbor distances associated with the candidate set of patterns 404 are in the range of 10-100 units, then the pattern coverage component 505 determines the number of patterns associated with various first nearest neighbor distances in that range. In some embodiments, the pattern coverage component 505 may generate a graph of the pattern coverage based on the first nearest neighbor distance and the count of patterns associated with various first nearest neighbor distances, as illustrated in a first graph 502. In the graphs 502-506, the x-axis may denote a first nearest neighbor distance and the y-axis may denote a count of the patterns.

The first graph 502 indicates a first pattern coverage of the selected set of patterns 402. In the first graph 502, it can be noted from the tail of the histogram that there are some patterns in the candidate set of patterns 404 with large first nearest neighbor distances (e.g., above a threshold first nearest neighbor distance). This may indicate that the candidate set of patterns 404 may still include some patterns that are diverse with respect to the selected set of patterns 402. Accordingly, the user may continue to select additional patterns from the candidate set of patterns 404 and add those patterns to the selected set of patterns 402. For example, the user may add a first number of patterns from the candidate set of patterns 404 to the selected set of patterns 402. In choosing the first number of patterns, the user may choose to add a pattern associated with the first nearest neighbor distance indicated by the end of the tail of the histogram as it indicates the largest first nearest neighbor distance. For example, the user may look at the feature vector distance table (e.g., Table 1A or Table 1B) and identify the specific pattern associated with the largest first nearest neighbor distance indicated by the end of the tail of the histogram.

A second graph 504 indicates a second pattern coverage of the selected set of patterns 402. As described above, the first nearest neighbor distances of some of the patterns of the candidate set of patterns 404 may change after moving some patterns from the candidate set of patterns 404 to the selected set of patterns 402A. The second graph 504 indicates a plot of the first nearest neighbor distances and the count of patterns associated with various first nearest neighbor distances after adding the first number of patterns to the selected set of patterns 402. In the second graph 504, it can be noted from the tail of the histogram that the largest first nearest neighbor distance has decreased from, or is smaller than, the largest first nearest neighbor distance in the first graph 502. Accordingly, the second graph 504 may indicate that the second pattern coverage is better or improved over the first pattern coverage. However, the user may further choose to improve the pattern coverage by adding additional patterns from the candidate set of patterns 404. For example, the user may add a second number of patterns from the candidate set of patterns 404 to the selected set of patterns 402.

A third graph 506 indicates a third pattern coverage of the selected set of patterns 402. The third graph 506 indicates a plot of the first nearest neighbor distances and the count of patterns associated with various first nearest neighbor distances after adding the second number of patterns to the selected set of patterns 402. In the third graph 506, it can be noted from the tail of the histogram that the number of patterns in the candidate set of patterns 404 with large first nearest neighbor distances (e.g., above a threshold first nearest neighbor distance) has further decreased compared to the second graph 504 and the first graph 502, and that the largest first nearest neighbor distance is smaller than the largest first nearest neighbor distance in the second graph 504. Accordingly, the third graph 506 may indicate that the third pattern coverage of the selected set of patterns 402 is better than, or has improved over, the second pattern coverage.

The pattern coverage graph may provide a guidance or an indication of how good the pattern coverage of the selected set of patterns 402 is, and may facilitate the user in determining whether to continue with selecting and adding additional patterns from the candidate set of patterns 404. The user may continue to select further patterns from the candidate set of patterns 404 until a specified pattern coverage criterion is satisfied-for example, the largest first nearest neighbor distance is less than a specified threshold, until a rate at which the largest first nearest neighbor distance decreases with every iteration is less than a threshold rate, etc. Note that the pattern coverage graph may be generated after every iteration of method 600 or after a specified number of iterations. After the pattern coverage is satisfied, the pattern selection component 430 may output the selected set of patterns 402.

In some embodiments, the selected set of patterns 402 may be used as training data to calibrate or train models (e.g., physical model, AI model, empirical model, rule-based model, etc.) configured to determine characteristics of a patterning process or a lithography apparatus used for printing a pattern on a substrate. A patterning process may be performed using the lithographic apparatus based on the determined characteristics to print patterns corresponding to the target layout on the substrate.

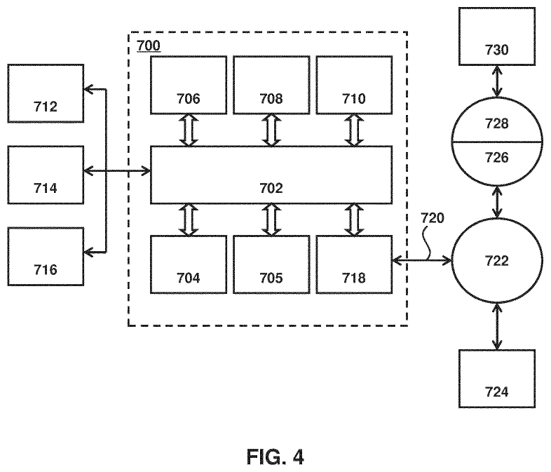

FIG. 4 is a block diagram that illustrates a computer system 700 which can assist in implementing in various methods and systems disclosed herein. The computer system 700 may be used to implement any of the entities, components, modules, or services depicted in the examples of the figures (and any other entities, components, modules, or services described in this specification). The computer system 700 may be programmed to execute computer program instructions to perform functions, methods, flows, or services (e.g., of any of the entities, components, or modules) described herein. The computer system 700 may be programmed to execute computer program instructions by at least one of software, hardware, or firmware.

Computer system 700 includes a bus 702 or other communication mechanism for communicating information, and a processor 704 (or multiple processors 704 and 705) coupled with bus 702 for processing information. Computer system 700 also includes a main memory 706, such as a random access memory (RAM) or other dynamic storage device, coupled to bus 702 for storing information and instructions to be executed by processor 704. Main memory 706 also may be used for storing temporary variables or other intermediate information during execution of instructions to be executed by processor 704. Computer system 700 further includes a read only memory (ROM) 708 or other static storage device coupled to bus 702 for storing static information and instructions for processor 704. A storage device 710, such as a magnetic disk or optical disk, is provided and coupled to bus 702 for storing information and instructions.

Computer system 700 may be coupled via bus 702 to a display 712, such as a cathode ray tube (CRT) or flat panel or touch panel display for displaying information to a computer user. An input device 714, including alphanumeric and other keys, is coupled to bus 702 for communicating information and command selections to processor 704. Another type of user input device is cursor control 716, such as a mouse, a trackball, or cursor direction keys for communicating direction information and command selections to processor 704 and for controlling cursor movement on display 712. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 700 in response to processor 704 executing one or more sequences of one or more instructions contained in main memory 706. Such instructions may be read into main memory 706 from another computer-readable medium, such as storage device 710. Execution of the sequences of instructions contained in main memory 706 causes processor 704 to perform the process steps described herein. One or more processors in a multi-processing arrangement may also be employed to execute the sequences of instructions contained in main memory 706. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 704 for execution. Such a medium may take many forms, including but not limited to, non-volatile media, volatile media, and transmission media. Non-volatile media include, for example, optical or magnetic disks, such as storage device 710. Volatile media include dynamic memory, such as main memory 706. Transmission media include coaxial cables, copper wire and fiber optics, including the wires that comprise bus 702. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 704 for execution. For example, the instructions may initially be borne on a magnetic disk of a remote computer. The remote computer can load the instructions into its dynamic memory and send the instructions over a telephone line using a modem. A modem local to computer system 700 can receive the data on the telephone line and use an infrared transmitter to convert the data to an infrared signal. An infrared detector coupled to bus 702 can receive the data carried in the infrared signal and place the data on bus 702. Bus 702 carries the data to main memory 706, from which processor 704 retrieves and executes the instructions. The instructions received by main memory 706 may optionally be stored on storage device 710 either before or after execution by processor 704.

Computer system 700 also preferably includes a communication interface 718 coupled to bus 702. Communication interface 718 provides a two-way data communication coupling to a network link 720 that is connected to a local network 722. For example, communication interface 718 may be an integrated services digital network (ISDN) card or a modem to provide a data communication connection to a corresponding type of telephone line. As another example, communication interface 718 may be a local area network (LAN) card to provide a data communication connection to a compatible LAN. Wireless links may also be implemented. In any such implementation, communication interface 718 sends and receives electrical, electromagnetic, or optical signals that carry digital data streams representing various types of information.

Network link 720 typically provides data communication through one or more networks to other data devices. For example, network link 720 may provide a connection through local network 722 to a host computer 724 or to data equipment operated by an Internet Service Provider (ISP) 726. ISP 726 in turn provides data communication services through the worldwide packet data communication network, now commonly referred to as the “Internet” 728. Local network 722 and Internet 728 both use electrical, electromagnetic, or optical signals that carry digital data streams. The signals through the various networks and the signals on network link 720 and through communication interface 718, which carry the digital data to and from computer system 700, are exemplary forms of carrier waves transporting the information.

Computer system 700 can send messages and receive data, including program code, through the network(s), network link 720, and communication interface 718. In the Internet example, a server 730 might transmit a requested code for an application program through Internet 728, ISP 726, local network 722 and communication interface 718. One such downloaded application may provide for the illumination optimization of the embodiment, for example. The received code may be executed by processor 704 as it is received, or stored in storage device 710, or other non-volatile storage for later execution. In this manner, computer system 700 may obtain application code in the form of a carrier wave.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Embodiments of the present disclosure can be further described by the following clauses.
1. A method for selecting patterns, the method comprising:
obtaining a first set of patterns and a second set of patterns represented in a pattern representation space;
obtaining, for each pattern in the second set of patterns, a similarity metric that is indicative of a similarity between the corresponding pattern and patterns in the first set of patterns, wherein the similarity is determined in the pattern representation space; and
selecting a specified pattern from the second set of patterns for updating the first set of patterns based on the similarity metric.
2. The method of clause 1, wherein the pattern representation space includes a feature vector space.
3. The method of clause 2, wherein the first set of patterns or the second set of patterns are represented in the feature vector space by encoding each pattern in the first set of patterns or the second set of patterns to a corresponding feature vector.
4. The method of clause 3, wherein the encoding includes encoding a target layout of the first set of patterns or the second set of patterns to the corresponding feature vector.
5. The method of clause 3, wherein the encoding includes encoding an image of a pattern in the first set of patterns or the second set of patterns to the corresponding feature vector.
6. The method of clause 3, wherein the encoding is based on an autoencoder model.
7. The method of clause 2, wherein the similarity metric includes distance information indicating distances in the feature vector space between the corresponding pattern in the second set of patterns and patterns in the first set of patterns.
8. The method of clause 7, wherein the distance information includes nearest neighbor distance between two feature vectors in the feature vector space.
9. The method of clause 7, wherein the distances for each pattern in the second set of patterns are ranked from a first nearest neighbor distance to a last nearest neighbor distance.
10. The method of clause 7, wherein selecting the specified pattern is based on a largest first nearest neighbor distance.
11. The method of clause 10, wherein the largest first nearest neighbor distance is indicative of a pattern among the second set of patterns that is least similar to any pattern of the first set of patterns.
12. The method of clause 2, wherein the first set of patterns includes patterns having nearest neighbor distances between other patterns in the first set of patterns above a specified threshold.
13. The method of clause 1, wherein the first set of patterns have less similarity between each other than with patterns in the second set of patterns.
14. The method of clause 1, wherein selecting the specified pattern includes moving the specified pattern from the second set of patterns to the first set of patterns.
15. The method of clause 1 further comprising:
updating the similarity metric for remaining patterns of the second set of patterns after moving the specified pattern to the first set of patterns.
16. The method of clause 1 further comprising:
iteratively selecting a pattern from the second set of patterns until a specified criterion is satisfied.
17. The method of clause 16, wherein each iteration includes:
selecting a pattern of the second set of patterns based on the similarity metric;
moving the pattern to the first set of patterns; and
updating the similarity metric for remaining patterns of the second set of patterns after moving the pattern to the first set of patterns.
18. The method of clause 16, wherein the specified criterion is based on at least one of (a) a number of iterations, (b) a number or percentage of patterns selected from the second set of patterns, (c) a total number of patterns in the first set of patterns, or (d) a first nearest neighbor distance.
19. The method of clause 16, wherein iteratively selecting the pattern includes:
determining a pattern coverage in the first set of patterns based on a number of patterns present in the first set of patterns associated with a given similarity metric value of a set of similarity metric value with the second set of patterns; and
determining whether to continue the iteratively selecting based on the pattern coverage.
20. The method of clause 1, wherein the pattern representation space includes an image representation space.
21. The method of clause 20, wherein the first set of patterns or the second set of patterns are represented in the image representation space by obtaining an image of each pattern in the first set of patterns or the second set of patterns.
22. The method of clause 21, wherein the similarity metric is indicative of a similarity between an image of each pattern in the second set of patterns and images of patterns in the first set of patterns.
23. The method of clause 1 further comprising:
calibrating, using the first set of patterns, a model configured to determine characteristics of a patterning process or a lithography apparatus used for printing a pattern on a substrate.
24. A method for selecting patterns, the method comprising:
obtaining a first set of patterns and a second set of patterns represented in a feature vector space; obtaining, for each pattern in the second set of patterns, distance information indicating distances in the feature vector space between the corresponding pattern and patterns in the first set of patterns; and selecting a specified pattern form the second set of patterns for updating the first set of patterns based on the distance information.
25. The method of clause 24, wherein the distance information includes nearest neighbor distance between two feature vectors in the feature vector space.
26. The method of clause 24, wherein the distances for each pattern in the second set of patterns are ranked from a first nearest neighbor distance to a last nearest neighbor distance.
27. The method of clause 24, wherein selecting the specified pattern is based on a largest first nearest neighbor distance.
28. The method of clause 24, wherein the first set of patterns includes patterns having nearest neighbor distances between other patterns in the first set of patterns above a specified threshold.
29. The method of clause 24, wherein the first set of patterns have less similarity between each other than with patterns in the second set of patterns.
30. The method of clause 24, wherein selecting the specified pattern includes moving the specified pattern from the second set of patterns to the first set of patterns.
31. The method of clause 24 further comprising:
updating the distance information for remaining patterns of the second set of patterns after moving the specified pattern to the first set of patterns.
32. The method of clause 24 further comprising:
iteratively selecting a pattern from the second set of patterns until a specified criterion is satisfied.
33. The method of clause 32, wherein each iteration includes:
selecting a pattern of the second set of patterns based on the distance information;
moving the pattern to the first set of patterns; and
updating distance information for remaining patterns of the second set of patterns after moving the pattern to the first set of patterns.
34. The method of clause 32, wherein the specified criterion is based on at least one of (a) a number of iterations, (b) a number or percentage of patterns selected from the second set of patterns, (c) a total number of patterns in the first set of patterns, or (d) a first nearest neighbor distance.
35. The method of clause 32, wherein iteratively selecting the pattern includes:
determining a pattern coverage in the first set of patterns based on a number of patterns present in the first set of patterns associated with a given nearest neighbor distance of a set of nearest neighbor distances with the second set of patterns; and
determining whether to continue the iteratively selecting based on the pattern coverage.
36. The method of clause 24, wherein obtaining the first set of patterns or the second set of patterns includes obtaining an image representation of the first set of patterns or the second set of patterns.
37. The method of clause 24, wherein obtaining the first set of patterns or the second set of patterns includes obtaining a target layout of the first set of patterns or the second set of patterns.
38. The method of clause 24, wherein the first set of patterns or the second set of patterns are represented in the feature vector space by encoding each pattern in the first set of patterns or the second set of patterns to a corresponding feature vector.
39. The method of clause 38, wherein the encoding is based on an autoencoder model.
40. The method of clause 24 further comprising:
calibrating, using the first set of patterns, a model configured to determine characteristics of a patterning process or a lithography apparatus used for printing a pattern on a substrate.
41. An apparatus comprising:
a memory storing a set of instructions; and
a processor configured to execute the set of instructions to cause the apparatus to perform a method of any of the above clauses.
42. A non-transitory computer-readable medium having instructions recorded thereon, the instructions when executed by a computer implementing the method of any of the above claims.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

The descriptions herein are intended to be illustrative, not limiting. Thus, it will be apparent to one skilled in the art that modifications may be made as described without departing from the scope of the claims set out below.

1. A non-transitory computer-readable medium having instructions recorded thereon or therein, the instructions, when executed by a computer system, are configured to cause the computer system to at least:
obtain a first set of patterns and a second set of patterns represented in a pattern representation space;
obtain for each pattern in the second set of patterns, a similarity metric that is indicative of a similarity between the corresponding pattern and patterns in the first set of patterns, wherein the similarity is determined in the pattern representation space; and
select a specified pattern from the second set of patterns for updating the first set of patterns based on the similarity metric.

2. The medium of claim 1, wherein the pattern representation space includes a feature vector space, and wherein the first set of patterns or the second set of patterns are represented in the feature vector space by encoding, based on an autoencoder model, each pattern in the first set of patterns or the second set of patterns to a corresponding feature vector.

3. The medium of claim 2, wherein the encoding includes encoding a target layout of the first set of patterns or the second set of patterns to the corresponding feature vector.

4. The medium of claim 2, wherein the encoding includes encoding an image of a pattern in the first set of patterns or the second set of patterns to the corresponding feature vector.

5. The medium of claim 2, wherein the similarity metric includes distance information indicating distances in the feature vector space between the corresponding pattern in the second set of patterns and patterns in the first set of patterns.

6. The medium of claim 5, wherein the distance information includes nearest neighbor distance between two feature vectors in the feature vector space.

7. The medium of claim 5, wherein the instructions configured to cause the computer system to select the specified pattern are further configured to cause the computer system to do so is based on a largest nearest neighbor distance, wherein the largest nearest neighbor distance is indicative of a pattern among the second set of patterns that is least similar to any pattern of the first set of patterns.

8. The medium of claim 1, wherein the first set of patterns includes patterns having nearest neighbor distances in the pattern representation space between other patterns in the first set of patterns above a specified threshold.

9. The medium of claim 1, wherein the instructions configured to cause the computer system to select the specified pattern are further configured to cause the computer system to move the specified pattern from the second set of patterns to the first set of patterns.

10. The medium of claim 9, wherein the instructions are further configured to cause the computer system to update the similarity metric for remaining patterns of the second set of patterns after movement of the specified pattern to the first set of patterns.

11. The medium of claim 1, wherein the instructions are further configured to cause the computer system to:
iteratively select a pattern from the second set of patterns until a specified criterion is satisfied, wherein each iteration includes:
selection of a pattern of the second set of patterns based on the similarity metric;
movement of the pattern to the first set of patterns; and
update of the similarity metric for remaining patterns of the second set of patterns after movement of the pattern to the first set of patterns.

12. The medium of claim 11, wherein the specified criterion is based on at least one selected from: (a) a number of iterations, (b) a number or percentage of patterns selected from the second set of patterns, (c) a total number of patterns in the first set of patterns, or (d) a nearest neighbor distance.

13. The medium of claim 11, wherein the instructions configured to cause the computer system to iteratively select the pattern are further configured to cause the computer system to:
determine a pattern coverage in the first set of patterns based on a number of patterns present in the first set of patterns associated with a given similarity metric value of a set of similarity metric values with the second set of patterns; and
determine whether to continue the iterative selection based on the pattern coverage.

14. The medium of claim 1, wherein the pattern representation space includes an image representation space,
wherein the first set of patterns or the second set of patterns are represented in the image representation space by obtaining an image of each pattern in the first set of patterns or the second set of patterns, and
wherein the similarity metric is indicative of a similarity between an image of each pattern in the second set of patterns and images of patterns in the first set of patterns.

15. The medium of claim 1, wherein the instructions are further configured to cause the computer system to calibrate, using the first set of patterns, a model configured to determine characteristics of a patterning process or a lithography apparatus used for printing a pattern on a substrate.

16. A non-transitory computer-readable medium having instructions recorded thereon or therein, the instructions, when executed by a computer system, are configured to cause the computer system to at least:
obtain a first set of patterns and a second set of patterns represented in a feature vector space;
obtain, for each pattern in the second set of patterns, distance information indicating distances in the feature vector space between the corresponding pattern and patterns in the first set of patterns; and
select a specified pattern from the second set of patterns for updating of the first set of patterns based on the distance information.

17. The medium of claim 16, wherein the distance information includes nearest neighbor distance between two feature vectors in the feature vector space.

18. The medium of claim 16, wherein the distances for the patterns in the second set of patterns are ranked from a first nearest neighbor distance to a last nearest neighbor distance.

19. The medium of claim 16, wherein the instructions configured to cause the computer system to select the specified pattern are configured to cause the computer system to do so based on a largest nearest neighbor distance.

20. The medium of claim 16, wherein the first set of patterns includes patterns having nearest neighbor distances between other patterns in the first set of patterns above a specified threshold.
